(19) United States
(12) Patent Application Publication
(10) Pub. No.: US 2018/0331265 A1
(43) Pub. Date: Nov. 15, 2018

(54) LAMP

(71) Applicants: Yung-Cheng Sung, Hsinchu (TW); Tzyy-Jang Tseng, Hsinchu (TW)

(72) Inventors: Yung-Cheng Sung, Hsinchu (TW); Tzyy-Jang Tseng, Hsinchu (TW)

(73) Assignee: APM COMMUNICATION, INC., Hsinchu (TW)

(21) Appl. No.: 15/700,184

(22) Filed: Sep. 11, 2017

(30) Foreign Application Priority Data
May 12, 2017 (TW) 106206777

(51) Int. Cl. H01L 33/64; H01L 33/48; F21V 19/00

(52) U.S. Cl. CPC H01L 33/644; F21Y 2115/10; F21V 19/003; H01L 33/486

(57) ABSTRACT

A lamp including light-emitting diode (LED) light bars and at least one fixing member is provided. The fixing member is fixed on a fixed surface of the LED light bars. The fixed surface is opposite to a light emitting surface of the LED light bars. The fixing member only covers a portion of the fixed surface.

### CROSS-REFERENCE TO RELATED APPLICATION

This application claims the priority benefit of Taiwan application serial no. 106206777, filed on May 12, 2017. The entirety of the above-mentioned patent application is hereby incorporated by reference herein and made a part of this specification.

### BACKGROUND OF THE INVENTION

### Field of the Invention

The invention relates to a lamp, and in particular, a lamp exhibiting improved heat dissipating effect.

### Description of Related Art

The light-emitting diode (LED) is a semiconductor device. Its light emission principle involves converting electrical energy into optical energy. A lifespan of the LED is one hundred thousand hours or more, and the LED further has advantages including quick response, a small size, low power consumption, low pollution, high reliability, and being suitable for mass production. Therefore, the LED is gradually penetrating general lighting lamp markets.

However, when LED light bars are used as a light source of a lamp, the LED light bars are generally fixed on a fixing plate, and no openings are provided on the entire fixing plate. Moreover, the fixing plate fully covers the LED light bars and obstructs airflow from circulating, which frequently results in an issue of undesirable heat dissipation.

### SUMMARY OF THE INVENTION

The invention provides a lamp which exhibits improved heat dissipating effect.

The invention provides a lamp including LED light bars and at least one fixing member. The fixing member is fixed on a fixed surface of the LED light bars. The fixed surface is opposite to a light emitting surface of the LED light bars. The fixing member only covers a portion of the fixed surface.

According to an embodiment of the invention, in the foregoing lamp, the LED light bars can be arranged to be spaced apart from each other by an interval.

According to an embodiment of the invention, in the foregoing lamp, each of the LED light bars can include a power source. The power source is located in one end of the LED light bar.

According to an embodiment of the invention, in the foregoing lamp, the fixing member can cover at least a portion of the power sources.

According to an embodiment of the invention, in the foregoing lamp, the power sources of two adjacent LED light bars can be located at a same end or different ends of the two adjacent LED light bars.

According to an embodiment of the invention, in the foregoing lamp, the fixing member can clamp or lock the LED light bars.

According to an embodiment of the invention, in the foregoing lamp, the fixing member, for example, fixes in a width direction of the LED light bars.

According to an embodiment of the invention, in the foregoing lamp, the fixing member can include at least one heat dissipation fin.

According to an embodiment of the invention, in the foregoing lamp, a number of the fixing member is plural, for example.

According to an embodiment of the invention, the foregoing lamp further includes at least one connecting member connecting between the fixing members.

In light of the above, in the lamp provided in the invention, since the fixing member only covers a portion of the fixed surface of the LED light bars and does not fully cover the fixed surface of the LED light bars, airflow can sufficiently circulate and further enable the lamp to exhibit improved heat dissipating effect. Moreover, since the fixing member of the lamp provided in the invention has a smaller size, manufacturing costs of the lamp are reduced, and a weight of the lamp and a volume before assembly are also reduced, which facilitates transportation of the lamp.

To provide a further understanding of the aforementioned and other features and advantages of the invention, exemplary embodiments, together with the reference drawings, are described in detail below.

### BRIEF DESCRIPTION OF THE DRAWINGS

FIG. 1 is a schematic diagram illustrating a lamp according to an embodiment of the invention.

FIG. 2 is a schematic diagram illustrating a lamp according to another embodiment of the invention.

### DESCRIPTION OF THE EMBODIMENTS

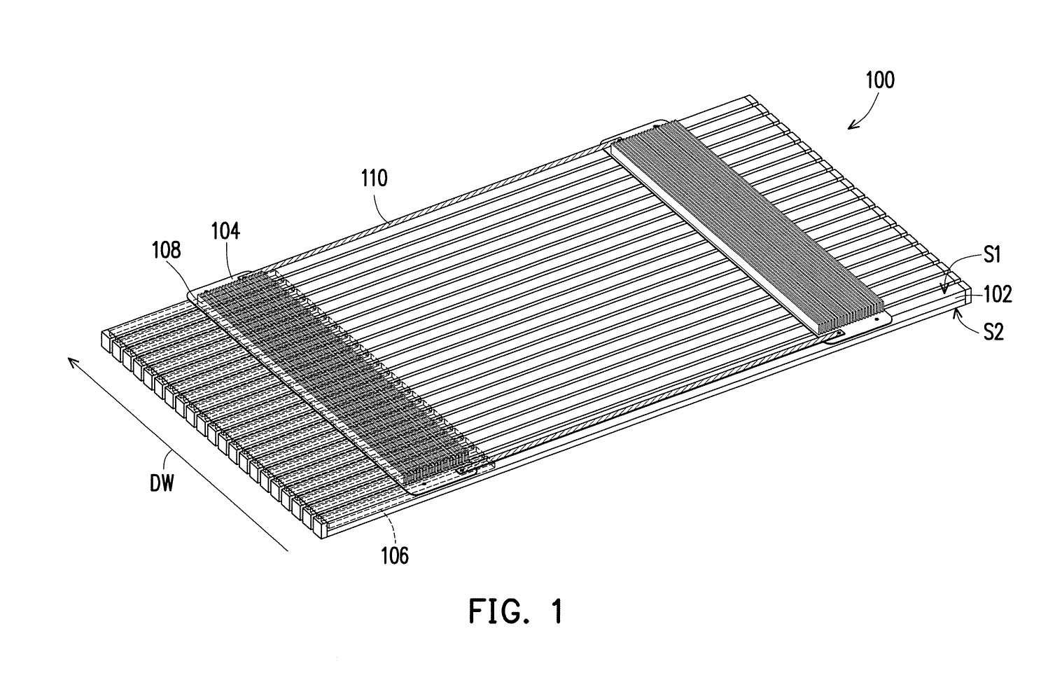

FIG. 1 is a schematic diagram illustrating a lamp according to an embodiment of the invention.

Referring to FIG. 1, a lamp 100 includes LED light bars 102 and at least one fixing member 104. In the present embodiment, a number of the fixing member 104 is plural, for example, in the description. The lamp 100 can be used in various lighting applications such as suspension lamps for plant lighting or office lights, for example.

The LED light bars 102 can be arranged to be spaced apart from each other by an interval to facilitate heat dissipation. Each of the LED light bars 102 can include a power source 106. The power source 106 is located in one end of the LED light bar 102. The power sources 106 of two adjacent LED light bars 102 can be located at the same end or different ends of the two adjacent LED light bars 102. In the present embodiment, the power sources 106 of two adjacent LED light bars 102 are, for example, located at the same end of the two LED light bars 102 in the description.

The fixing member 104 is fixed on a fixed surface S1 of the LED light bars 102 to fix the LED light bars 102. The fixed surface S1 is opposite to a light emitting surface S2 of the LED light bars 102. The fixing member 104 fixes, for example, in a width direction DW of the LED light bars 102. A material of the fixing member 104 is, for example, aluminum or aluminum alloy. The fixing member 104 can include at least one heat dissipation fin 108. The heat dissipation fin 108 contributes to heat dissipation. In the present embodiment, a number of the heat dissipation fin 108 is plural, for example, in the description.

For example, the fixing member 104 can clamp or lock the LED light bars 102. Specifically, the fixing member 104 can clamp the LED light bars 102 by means of a clamping member (not illustrated) or can lock the LED light bars 102 by means of screws (not illustrated).

The fixing member 104 only covers a portion of the fixed surface S1, such that airflow can sufficiently circulate and further enable the lamp 100 to exhibit improved heat dissipating effect. Moreover, the fixing member 104 can cover at least a portion of the power source 106, which contributes to outward conduction of heat of the power source 106 and further enhances the heat dissipating effect. A size of the fixing members 104 can be identical or different from each other.

In addition, in the case where the number of the fixing member 104 is plural, the lamp 100 can further include at least one connecting member 110. The connecting member 110 connects between the fixing members 104 to reinforce the fixing effect. For example, the connecting member 110 and the fixing members 104 can be connected to each other by means of screws (not illustrated). A material of the connecting member 110 is, for example, aluminum or aluminum alloy. In the present embodiment, a number of the connecting member 110 is plural, for example, in the description.

In light of the foregoing embodiment, in the lamp 100, since the fixing member 104 only covers a portion of the fixed surface S1 of the LED light bars 102 and does not fully cover the fixed surface S1 of the LED light bars 102, airflow can sufficiently circulate and further enable the lamp 100 to exhibit improved heat dissipating effect. Moreover, since the fixing member 104 of the lamp 100 has a smaller size, manufacturing costs of the lamp 100 are reduced, and a weight of the lamp 100 and a volume before assembly are also reduced, which facilitates transportation of the lamp 100.

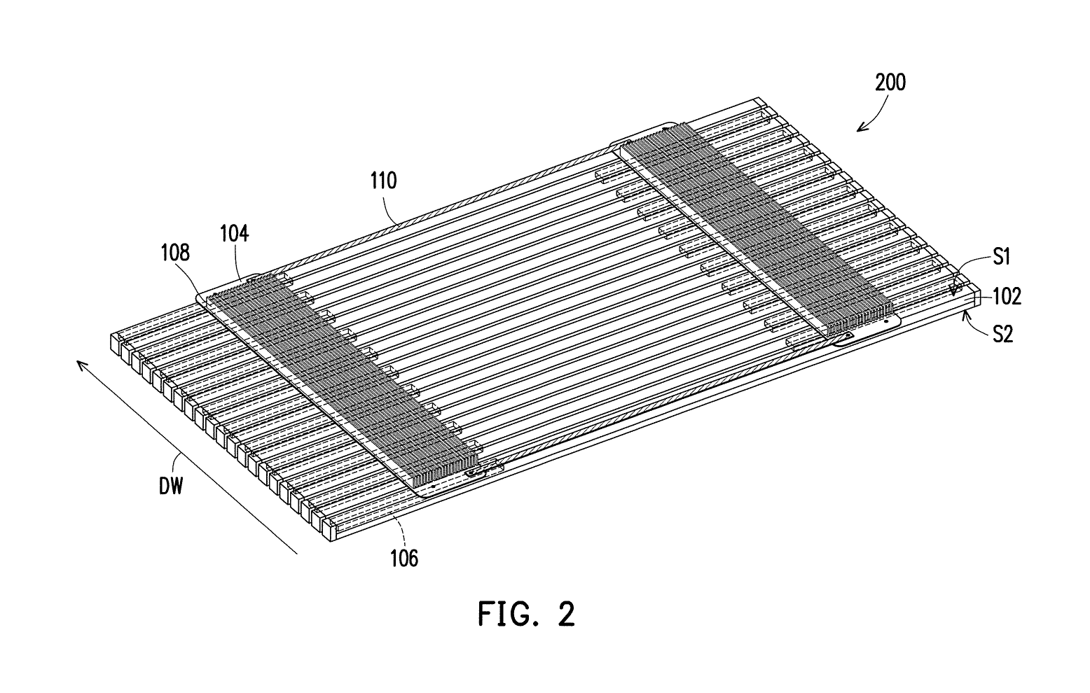

FIG. 2 is a schematic diagram illustrating a lamp according to another embodiment of the invention.

Referring to both FIG. 1 and FIG. 2, a lamp 200 of FIG. 2 exhibits the following difference from the lamp 100 of FIG. 1. In the lamp 200 of FIG. 2, the power sources 106 of two adjacent LED light bars 102 are located at different ends of the two adjacent LED light bars 102. In other words, the power sources 106 are alternately arranged at one end and the other end of the LED light bars 102. Such arrangement can prevent the power sources 106 of the two adjacent LED light bars 102 from generating a high temperature due to an overly short distance therebetween and further contributes to lowering a temperature of the lamp 200. Moreover, similar components in the lamp 200 and the lamp 100 are labeled with the same numerals and descriptions thereof are omitted.

In summary of the above, in the lamp of the foregoing embodiments, since the fixing member only covers a portion of the fixed surface of the LED light bars, improved heat dissipating effect is achieved. Moreover, the fixing member of the lamp has a smaller size, which reduces manufacturing costs of the lamp and facilitates transportation of the lamp.

Although the invention is disclosed as the embodiments above, the embodiments are not meant to limit the invention. Any person skilled in the art may make slight modifications and variations without departing from the spirit and scope of the invention. Therefore, the protection scope of the invention shall be defined by the claims attached below.

What is claimed is:

1. A lamp, comprising:
light-emitting diode (LED) light bars; and
at least one fixing member fixed on a fixed surface of the LED light bars, wherein the fixed surface is opposite to a light emitting surface of the LED light bars, and the at least one fixing member only covers a portion of the fixed surface.

2. The lamp according to claim 1, wherein the LED light bars are arranged to be spaced apart from each other by an interval.

3. The lamp according to claim 1, wherein each of the LED light bars comprises a power source located in one end of each of the LED light bars.

4. The lamp according to claim 3, wherein the at least one fixing member covers at least a portion of the power sources.

5. The lamp according to claim 3, wherein the power sources of two adjacent LED light bars are located at a same end or different ends of the two adjacent LED light bars.

6. The lamp according to claim 1, wherein the at least one fixing member clamps or locks the LED light bars.

7. The lamp according to claim 1, wherein the at least one fixing member fixes in a width direction of the LED light bars.

8. The lamp according to claim 1, wherein the at least one fixing member comprises at least one heat dissipation fin.

9. The lamp according to claim 1, wherein a number of the at least one fixing member is plural.

10. The lamp according to claim 9, further comprising at least one connecting member connecting between the fixing members.
